(19) United States
(12) Patent Application Publication
(10) Pub. No.: US 2026/0121000 A1
(43) Pub. Date: Apr. 30, 2026

(54) SUBSTRATE PROCESSING APPARATUS

(71) Applicant: TES CO., LTD, Yongin-si (KR)

(72) Inventor: Jae-Woo KIM, Yongin-si (KR)

(73) Assignee: TES CO., LTD, Yongin-si (KR)

(21) Appl. No.: 19/359,664

(22) Filed: Oct. 15, 2025

(30) Foreign Application Priority Data
Oct. 28, 2024 (KR) 10-2024-0148479

(51) Int. Cl. H01J 37/32

(52) U.S. Cl. CPC H01J 37/3244; H01J 37/32715

(57) ABSTRACT

A substrate processing apparatus including a chamber, an upper showerhead, and a substrate support, is disclosed. The chamber is configured to provide a processing space for a substrate, and the upper showerhead is provided at an upper region of an interior of the chamber. The substrate support includes a substrate holder configured to support a lower surface of an edge of the substrate, and a lower showerhead provided at a lower region of the interior of the chamber and configured to supply process gas toward a lower surface of the substrate. The substrate holder is formed with a supply hole which is configured to supply the process gas toward a bevel of the substrate.

### CROSS-REFERENCE TO RELATED APPLICATIONS

A claim for priority under 35 U.S.C. § 119 is made to Korean Patent Application No. 10-2024-0148479 filed on October 28, 2024, in the Korean Intellectual Property Office, the entire contents of which are hereby incorporated by reference.

### BACKGROUND OF THE INVENTION

### Field of the Invention

The present invention relates to a substrate processing apparatus, and more particularly to the substrate processing apparatus capable of etching a lower surface and a bevel of a substrate by a single process.

### Description of the Related Art

Generally, when various patterns are formed on a top surface or an upper surface of a substrate, a thin film can be deposited on a lower surface or a bottom surface of the substrate to prevent damage to the substrate and compensate for substrate deflection. Such a thin film deposited on the lower or bottom surface of the substrate can be removed during the process through etching or similar steps.

However, when the thin film is deposited on the lower or bottom surface of the substrate, this thin film can also be deposited on a bevel of the substrate in addition to the lower or bottom surface. Thus, it is required to remove the thin film deposited on the bevel of the substrate as well.

In apparatuses based on conventional art, either separate devices are provided to remove the thin film on the bottom or lower surface of the substrate and the thin film on the bevel of the substrate, or separate processes are used to remove the thin film on the bottom or lower surface of the substrate and the thin film on the bevel of the substrate. This requires a large installation area for the devices and, furthermore, the etching process consumes significant amounts of time and cost.

### SUMMARY OF THE INVENTION

The present invention is contemplated to solve problems in the prior art mentioned above. Thus, it is an object of the present invention to provide a substrate processing apparatus capable of etching a lower surface and a bevel of a substrate by a single process.

To achieve the above object, the present invention may provide a substrate processing apparatus comprising: a chamber configured to provide a processing space for a substrate; an upper showerhead provided at an upper region of an interior of the chamber; and a substrate support including: a substrate holder configured to support a lower surface of an edge of the substrate; and a lower showerhead provided at a lower region of the interior of the chamber and configured to supply process gas toward a lower surface of the substrate, wherein the substrate holder is formed with a supply hole which is configured to supply the process gas toward a bevel of the substrate.

Here, the supply hole may be formed to be inclined upwardly toward the bevel of the substrate at the substrate holder.

Further, a plurality of supply holes may be provided to the substrate holder and may be spaced apart at equal intervals along the edge of the substrate at the substrate holder.

Moreover, the substrate processing apparatus may further comprise an RF power supply connected to any one of the upper showerhead and the substrate support, wherein radicals are supplied toward the bevel of the substrate via the supply hole, by generating plasma between the lower surface of the substrate and the lower showerhead.

Meanwhile, the substrate processing apparatus may further comprise a supply ring resting on an upper surface of the substrate holder and configured to guide the process gas supplied through the supply hole toward the bevel of the substrate.

In this case, the supply ring may be configured to cover the supply hole, and a recess may be formed on a lower surface of the supply ring to supply the process gas toward the bevel of the substrate.

Further, the recess may be opened toward the substrate at the lower surface of the supply ring.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is a side view illustrating an enlarged upper portion of a substrate holder of the substrate processing apparatus according to one embodiment;

FIG. 3 is a plan view of a substrate support viewed from a top; and

FIG. 4 is a side view illustrating an enlarged upper portion of a substrate holder in a substrate processing apparatus according to another embodiment.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as "comprise", “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to an embodiment of the present invention will be specifically described with reference to drawings.

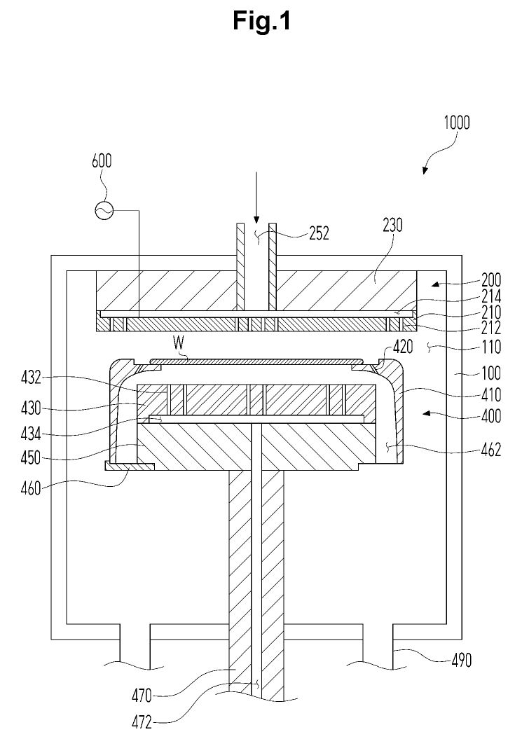

FIG. 1 is a side sectional view of a substrate processing apparatus 1000 according to one embodiment of the present invention.

Referring to FIG. 1, the substrate processing apparatus 1000 may include a chamber 100 providing a processing space 110 for a substrate W, an upper showerhead 200 provided at an upper region of an interior of the chamber 100, and a lower showerhead 430 provided at a lower region of the interior of the chamber 100 to supply process gas toward a lower surface (or a bottom surface) of the substrate W.

The substrate processing apparatus 1000 may be equipped with the chamber 100 providing the processing space 110 therein.

The chamber 100 may provide the processing space 110 in which a deposition process for the substrate W is performed, in the interior thereof.

The upper region of the interior of the chamber 100 may be provided with the upper showerhead 200 for supplying inert gas toward an upper surface (or a top surface) of the substrate W. Hereinafter, the upper surface of the substrate W also indicates the top surface thereof, and likewise, the lower surface of the substrate W also indicates the bottom surface thereof. Such indication may be applied to components of the substrate processing apparatus 100, in addition to the substrate W.

The upper showerhead 200 may include an upper showerhead plate 210, and an upper heater 230 provided on an upper portion of the upper showerhead plate 210. The upper showerhead plate 210 may be provided with a plurality of upper through holes 212.

At an upper portion of the chamber 100, an upper supply line 252 to which the inert gas or the like is supplied, may be connected. The inert gas supplied along the upper supply line 252 may be supplied through an upper diffuser 214, and then through the upper showerhead plate 210, to the upper surface of the substrate W.

The upper showerhead 200 may be connected to an RF power supply 600 to be supplied with RF power. That is, the upper showerhead 200 may serve as an upper electrode, and a substrate support 400 is grounded to serve as a lower electrode.

Also, although not shown in the drawings, a configuration in which the RF power supply 600 is connected to the substrate support 400 and the upper showerhead 200 is grounded, is available. That is, any one of the upper showerhead 200 and the substrate support 400 is connected to the RF power supply 600, and the other thereof may be grounded.

Meanwhile, the lower region of the interior of the chamber 100 may be provided with the substrate support 400 on which the substrate W is seated and supported.

The substrate support 400 may be configured to be movable in up and down directions in a lower region of the processing space 110. The substrate support 400 may support an edge of the lower surface of the substrate W, to supply the process gas toward the lower surface of the substrate W.

The substrate support 400 is connected to an actuation bar 470 extending downwardly, and the actuation bar 470 is connected to an actuation unit (not shown), such as a motor or the like, such that the actuation bar 470 and the substrate support 400 may move up and down by actuation of the actuation unit.

Specifically, the substrate support 400 may include a substrate holder 410 which supports the lower surface of the edge of the substrate W, and the lower showerhead 430 provided in the lower region of the interior of the substrate holder 410 to supply the process gas toward the lower surface of the substrate W. In addition, the substrate support 400 may further include a lower plate 450 which supports the lower showerhead 430.

The substrate holder 410 may support the lower surface of the edge of the substrate W.

In this case, the lower showerhead 430 may be provided within the interior of the substrate holder 410.

The process gas is supplied via a lower supply line 472 which passes through the actuation bar 470, and the process gas supplied along the lower supply line 472 is supplied to the lower showerhead 430 through a lower diffuser 434. The process gas supplied to the lower showerhead 430 may be supplied to the lower surface of the substrate W through a lower through hole 432.

In this case, if the RF power supply 600 is connected to the upper showerhead 200, the lower showerhead 430 may be grounded to generate plasma between the substrate W and the lower showerhead 430.

Meanwhile, a heat exchange path (not shown) may be formed in the lower plate 450, and a heat exchange fluid or the like may flow along the heat exchange path to adjust a temperature of the process gas or a temperature inside the chamber 100 via heat exchange.

Further, the lower plate 450 may serve to support the lower showerhead 430 and the substrate holder 410.

In this case, the lower showerhead 430 may be connected to an upper surface or a top surface of the lower plate 450, and the lower supply line 472 may be connected to the lower diffuser 434 by passing through the actuation bar 470 and the lower plate 450.

Additionally, a fixing member (or fixture) 460 supporting a lower end portion of the substrate holder 410, may be connected to the lower plate 450.

At this point, the fixing member 420 does not completely seal and couple the lower end portion of the substrate holder 410 and the lower plate 450, and instead, a plurality of fixing members 420 may be provided to the substrate support 400 and spaced apart at predetermined intervals along an outer circumference of the lower plate 450.

In other words, when the plurality of fixing members 420 are provided, spaces between neighboring fixing members 420 may be open downward to communicate with the interior of the chamber 100. Thus, a space between side surfaces of the lower showerhead 430 and the lower plate 450 and the inner opposite surface of the substrate holder 410 may form an exhaust path 462.

In this case, the process gas supplied from the lower showerhead 430 may be exhausted through the exhaust path 462 to the lower region of the interior of the chamber 100, and may be exhausted to an exterior of the chamber 100 through an exhaust outlet 490 provided at a lower portion of the chamber 100.

In the substrate processing apparatus 1000 having the configuration described above, the process gas may be supplied from the lower showerhead 430 toward the lower surface of the substrate W, and the plasma may be generated by such process gas.

For example, if a thin film deposited on the lower surface of the substrate W is to be removed, the process gas for etching may be supplied from the lower showerhead 430, and the process gas may be activated by the plasma and remove the thin film on the lower surface of the substrate W.

However, when the thin film is deposited on the lower surface of the substrate W to prevent damage to the substrate W, such a thin film may be deposited on a bevel in addition to the lower surface of the substrate W.

In apparatuses according to conventional art, separate devices are provided to remove the thin films on the lower surface and the bevel of the substrate W, and thus separate processes are used to remove the thin films from the lower surface and the bevel of the substrate W. These separate devices and processes consume significant time and cost.

The present invention is implemented to provide the substrate processing apparatus in which the thin film on the lower surface and the thin film on the bevel in the substrate W are not removed by the separate devices or processes, but can be removed by a single process and a single apparatus.

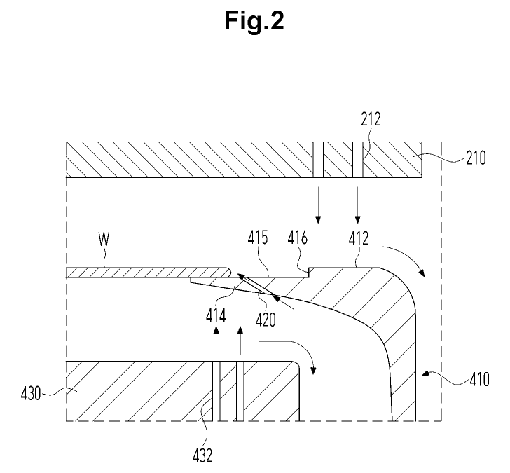

FIG. 2 is a side view illustrating an enlarged upper portion of the substrate holder 410 of the substrate processing apparatus 1000 as shown in FIG. 1.

Referring to FIG. 2, the substrate processing apparatus 1000 may include a supply hole 420 formed at the substrate holder 410, which is able to supply the process gas toward the bevel of the substrate W.

The supply hole 420 may be formed by passing through the substrate holder 410. For example, an upper portion of the substrate holder 410 may include a horizontal supporter 414 that is bent inwardly or extends inwardly.

A step 416 may be formed on an upper surface (or a top surface) 412 at an inner edge of the horizontal supporter 414, such that the lower surface of the edge of the substrate W may be supported by resting on a recess surface 415 of the horizontal supporter 414.

In this case, the supply hole 420 may be formed at the horizontal supporter 414. For example, when the substrate W is rested or seated on the recess surface 415 of the step 416, a gap or a clearance may exist between the edge of the substrate W and the step 416. The supply hole 420 may be provided in the gap between the edge of the substrate W and the step 416 at the horizontal supporter 414.

Meanwhile, the supply hole 420 may be formed to be inclined, slanted, tilted, or sloped toward the bevel of the substrate W. For example, as shown in FIG. 2, the supply hole 420 may be formed by inclining upwardly toward the bevel of the substrate W. As a result, a lower portion of the supply hole 420 may be formed by inclining downwardly toward a radially outward direction of the substrate W, and an upper portion of the supply hole 420 may be formed by inclining upwardly toward a radially inward direction of the substrate W.

By such a configuration of the supply hole 420, radicals or the like introduced through an inlet of the lower portion of the supply hole 420 may be supplied toward the bevel of the substrate W through an outlet of the upper portion of the supply hole 420.

Therefore, when the process gas, i.e., the etching gas is supplied toward the lower surface of the substrate W through the lower through hole 432 of the lower showerhead 430, and the RF power is supplied by the RF power supply 600, the plasma may be generated between the lower surface of the substrate W and the lower showerhead 430. By such plasma, the lower surface of the substrate W may be etched.

Further, some radicals of the plasma may be supplied toward the bevel of the substrate W through the supply hole 420 to etch the bevel of the substrate W.

Meanwhile, the inert gas supplied from the upper showerhead 200 toward the upper surface of the substrate W may flow to the lower region of the chamber 100 together with the etching gas supplied through the supply hole 420 and may be discharged to the outside of the chamber 100 through the exhaust outlet 490.

Meanwhile, a downward airflow is formed by pumping downwardly in the interior of the substrate support 400, and a downward airflow may also be formed by pumping radially on the upper portion of the substrate W. Even in such a case, near the bevel of the substrate W, the purge gas supplied from the upper showerhead 200 may form a horizontal laminar flow in a radial direction, so that a negative pressure may be formed at the outlet of the upper portion of the supply hole 420. Thus, the radicals that have reached the inlet of the lower portion of the supply hole 420 may be supplied toward the bevel of the substrate W through the supply hole 420 by the negative pressure at the supply hole 420, despite the downward airflow inside the substrate support 400.

Further, although not shown in the accompanying drawings, it is also possible that the supply hole 420 is not in a straight form, but in a bent or curved shape in the form of an arc. For example, when the lower portion of the supply hole 420 is inclined in the radially outward direction of the substrate W, and the upper portion of the supply hole 420 is inclined in the radially inward direction, a configuration connecting the upper and lower portions of the supply hole 420 in the form of an arc is also possible. In this case, the inlet of the lower part of the supply hole 420 is directed or oriented toward a direction in which the radicals flow in, and thus the inflow or introduction of the radicals may be smoother. Moreover, the outlet of the upper portion of the supply hole 420 may be directed or oriented toward the bevel of the substrate W, which may facilitate the supply of radicals toward the bevel of the substrate W.

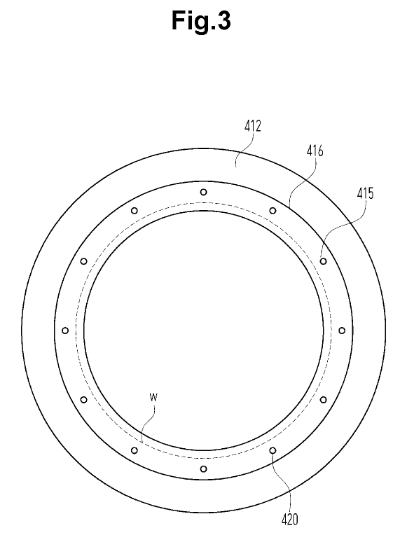

Meanwhile, FIG. 3 is a plan view of the substrate support 400 viewed from the top.

Referring to FIG. 3, a plurality of supply holes 420 may be provided to the substrate support 400, particularly to the substrate holder 410 and may be spaced apart at equal intervals along the edge of the substrate W at the substrate holder 410.

For example, the plurality of supply holes 420 may be formed along a circumferential direction at the recess surface 415 of the step 416 of the substrate support 400. In this case, the supply holes 420 may be disposed by being equally spaced apart along the edge of the substrate W.

As such, when the plurality of supply holes 420 are disposed at equal intervals, the bevel of the substrate W may be uniformly etched.

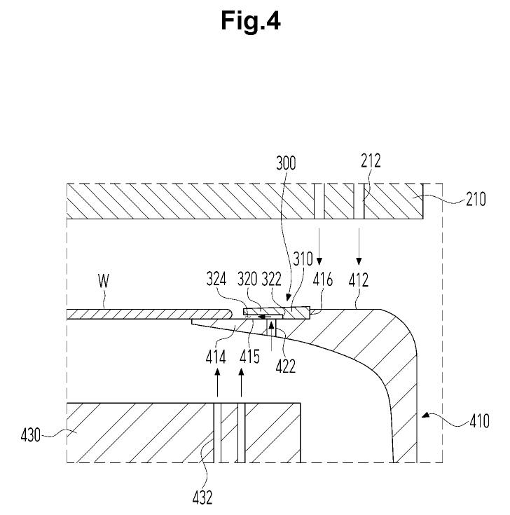

FIG. 4 is a side view illustrating an enlarged view of an upper portion of an substrate holder 410 in a substrate processing apparatus according to another embodiment.

Referring to FIG. 4, the substrate processing apparatus 1000 may further include a supply ring 300 that rests on the upper surface of the substrate holder 410. The supply ring 300 may guide the process gas supplied through the supply hole 422 toward the bevel of the substrate W.

The supply ring 300 may be supported by being seated on the step 416 of the horizontal supporter 414. The supply ring 300 may include a body 310, and an extension 320 extending from the body 310. In this case, a thickness of the extension 320 may be less than a thickness of the body 310.

That is, a recess 322 may be formed on a lower surface or a bottom surface of the supply ring 300. In this case, the supply ring 300 may be arranged to cover the supply hole 422. Specifically, the recess 322 of the supply ring 300 may be arranged to cover the supply hole 422.

By the configuration described above, a space 324 between the recess surface 415 of the horizontal supporter 414 and the recess 322 of the supply ring 300 may form a space through which the process gas supplied from the supply hole 422 is guided.

Further, the recess 322 may be formed or extended toward an inward side or toward the substrate W, at the lower (or bottom) surface of the supply ring 300. Thus, the process gas or the radicals or the like supplied through the supply hole 422 may be supplied toward the bevel of the substrate W along the arrow to etch the bevel of the substrate W.

In the present embodiment, the supply hole 422 is shown as vertically penetrating the horizontal supporter 414, but is not limited thereto and may be inclined toward the bevel of the substrate W as shown in the embodiment of FIG. 2.

The substrate processing apparatus according to the present invention has the technical advantages as follows.

According to the present invention having the configuration described above, the thin film deposited on the lower surface and the bevel of the substrate can be removed by the single process with the single apparatus without using the separate apparatuses and the separate processes, and thus time and cost required for the process can be significantly reduced.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber configured to provide a processing space for a substrate;
an upper showerhead provided at an upper region of an interior of the chamber; and
a substrate support including:
a substrate holder configured to support a lower surface of an edge of the substrate; and
a lower showerhead provided at a lower region of the interior of the chamber and configured to supply process gas toward a lower surface of the substrate,
wherein the substrate holder is formed with a supply hole which is configured to supply the process gas toward a bevel of the substrate.

2. The substrate processing apparatus of claim 1, wherein the supply hole is formed to be inclined upwardly toward the bevel of the substrate at the substrate holder.

3. The substrate processing apparatus of claim 1, wherein a plurality of supply holes are provided to the substrate holder and are spaced apart at equal intervals along the edge of the substrate at the substrate holder.

4. The substrate processing apparatus of claim 1, further comprising an RF power supply connected to any one of the upper showerhead and the lower showerhead,
wherein radicals are supplied toward the bevel of the substrate via the supply hole, by generating plasma between the lower surface of the substrate and the lower showerhead.

5. The substrate processing apparatus of claim 1, further comprising a supply ring resting on an upper surface of the substrate holder and configured to guide the process gas supplied through the supply hole toward the bevel of the substrate.

6. The substrate processing apparatus of claim 5, wherein the supply ring is configured to cover the supply hole, and a recess is formed on a lower surface of the supply ring to supply the process gas toward the bevel of the substrate.

7. The substrate processing apparatus of claim 6, wherein the recess is opened toward the substrate at the lower surface of the supply ring.
